(19) United States
(12) Patent Application Publication
(10) Pub. No.: US 2011/0019077 A1
(43) Pub. Date: Jan. 27, 2011

(54) CAMERA MODULE FABRICATING METHOD AND CAMERA MODULE

(75) Inventors: Masaru Kobayashi, Saitama-ken (JP); Katsuo Iwata, Kanagawa-ken (JP); Toyokazu Aizawa, Kanagawa-ken (JP); Takehiro Hiramatsu, Kanagawa-ken (JP); Takuro Obara, Kanagawa-ken (JP); Tatsuhiko Hagihara, Saitama-ken (JP); Hiromichi Kobayashi, Saitama-ken (JP); Shinichi Nitta, Kanagawa-ken (JP); Manabu Yamada, Tokyo (JP); Yasunari Fujii, Kanagawa-ken (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/836,159

(22) Filed: Jul. 14, 2010

(30) Foreign Application Priority Data
Jul. 22, 2009 (JP) 2009-171476

(51) Int. Cl. H04N 5/225; H01L 31/18

(52) U.S. Cl. 348/374; 438/65; 257/E31.117; 348/E05.025

(57) ABSTRACT

There is disclosed a method for fabricating a camera module includes the steps of: disposing a camera module body inside of a die; filling the die with a resin blocking a light; curing the resin; and removing the camera module body and the resin from the die. Here, disposing the camera module body inside of the die is disposing the camera module body having a lens holder secured on a sensor board inside of the die in such a manner that the side surface of the camera module body is not brought into contact with the side surface of the die. Filling the die with the resin is covering the upper end of the die with a lid so as to closely enclose the inside of the die, followed by filling the die with the resin. Taking the camera module body and the resin from the die is taking, from the die, the camera module body and the resin formed around the camera module body in close contact.

### CROSS REFERENCE TO RELATED APPLICATIONS

This application is based upon and claims the benefit of priority from the prior Japanese Patent Application No. 2009-171476 filed in Japan on Jul. 22, 2009; the entire contents of which are incorporated herein by reference.

### FIELD

Embodiments described herein relate generally to a camera module fabricating method and a camera module.

### BACKGROUND

A conventional small-sized camera module to be mounted on a mobile cellular phone, a mobile game machine, a PDA, a personal computer, or the like includes a camera module body provided with a lens holder having a sensor substrate, a lens, and the like incorporated therein and a shield blocking a magnetism or a light formed in such a manner as to surround the body.

The conventional camera module is configured to have a clearance of, for example, about 50 μm defined between the camera module body and the shield. The clearance is defined so as to prevent the camera module body from being broken when the camera module is fabricated by an automatic assembling device. Specifically, component parts constituting the camera module are located at desired positions by the automatic assembling device. In actuality, the component parts are deviated from their desired positions. In addition, the sizes of the component parts to be located at the desired positions are various. As a consequence, when the camera module body is secured inside of the shield, the camera module body may possibly collide against the shield. The above-described clearance is defined to prevent the camera module body from being broken by such a collision.

However, the clearance defined between the camera module body and the shield is a factor preventing miniaturization of the camera module.

There has been known another conventional camera module in which a lens, a lens holder, and a shield bloc king a light are formed integrally with each other. In the camera module, the lens holder and the shield are integrated with each other, and therefore, no clearance is defined between the lens holder and the shield. Therefore, the camera module could be seemingly miniaturized. However, in the case where the conventional camera module is to be further miniaturized, the lens holder including the shield need be thinly formed at the side surface thereof. Consequently, the mechanical strength of the lens holder is degraded according to the miniaturization, and at the same time, the thickness of the shield is decreased, thereby raising a problem of deterioration of light blocking effect. In view of this, in the case of the miniaturization of the camera module, another shield blocking a light need further cover the entire camera module. Thus, the miniaturization of the camera module is difficult even in the conventional camera module in which the lens, the lens holder, and the shield are formed integrally with each other.

### BRIEF DESCRIPTION OF THE DRAWINGS

FIG. 1 is a perspective view showing a camera module fabricated by a camera module fabricating method in embodiments according to the present invention;

FIG. 2 is a cross-sectional view showing the camera module, taken along a line X-X′ of FIG. 1;

FIG. 3 is a view illustrating a camera module fabricating method in a first embodiment according to the present invention, explanation of process of forming a shield blocking a light and corresponding to FIG. 2;

FIG. 4 is another view illustrating the camera module fabricating method in the first embodiment according to the present invention, explanation of process of forming a shield blocking a light and corresponding to FIG. 2;

FIG. 5 is a further view illustrating the camera module fabricating method in the first embodiment according to the present invention, explanation of process of forming a shield blocking a light and corresponding to FIG. 2;

FIG. 6 is a view illustrating a camera module fabricating method in a second embodiment according to the present invention, explanation of process of forming a plurality of camera module bodies and corresponding to FIG. 2;

FIG. 7 is another view illustrating the camera module fabricating method in the second embodiment according to the present invention, explanation of process of forming a plurality of camera module bodies and corresponding to FIG. 2;

FIG. 8 is a further view illustrating the camera module fabricating method in the second embodiment according to the present invention, explanation of process of forming a shield blocking a light in each of the plurality of camera module bodies and corresponding to FIG. 2;

FIG. 9 is a still further view illustrating the camera module fabricating method in the second embodiment according to the present invention, explanation of process of forming a shield blocking a light in each of the plurality of camera module bodies and corresponding to FIG. 2;

FIG. 10 is a still further view illustrating the camera module fabricating method in the second embodiment according to the present invention, explanation of process of forming a shield blocking a light in each of the plurality of camera module bodies and corresponding to FIG. 2;

FIG. 11 is a perspective view showing a first modification of the camera module fabricated by the camera module fabricating method in each of the embodiments according to the present invention;

FIG. 12 is a cross-sectional view showing the camera module, taken along a line Y-Y′ of FIG. 11;

FIG. 13 is a perspective view showing a second modification of the camera module fabricated by the camera module fabricating method in each of the embodiments according to the present invention; and

FIG. 14 is a cross-sectional view taken along a line Z-Z′ of FIG. 13.

### DESCRIPTION OF THE EMBODIMENTS

A method for fabricating a camera module in the embodiments according to the present invention includes the steps of: disposing a camera module body inside of a die; filling the die with an resin blocking a light; curing the resin; and taking the camera module body and the resin from the die. Here, disposing the camera module body inside of the die is disposing the camera module body having a lens holder secured above a sensor board inside of the die in such a manner that the side surface of the camera module body is not brought into contact with the side surface of the die. Filling the die with the resin is covering the upper end of the die with a lid so as to closely enclose the inside of the die, followed by filling the die with the resin. Taking the camera module body and the resin from the die is taking, from the die, the camera module body and the resin formed around the camera module body in close contact.

Furthermore, a method for fabricating a camera module in the embodiments according to the present invention includes the steps of: securing a plurality of lens holders on a wafer; securing a support board at the reverse of the wafer; forming a plurality of camera module bodies; disposing the plurality of camera module bodies inside of a die; filling the die with an resin blocking a light; curing the resin; taking the plurality of camera module bodies and the resin from the die; taking out the support board from the plurality of camera module bodies; and dicing the resin. Here, forming the plurality of camera module bodies is taking the wafer exposed to a clearance between the lens holders so as to form the plurality of camera module bodies on the support board. Disposing the plurality of camera module bodies inside of the die is disposing the support board having the plurality of camera module bodies inside of the die in such a manner that the side surface of the plurality of camera module bodies are not brought into contact with the side surface of the die. Filling the die with the resin is covering the upper end of the die with a lid so as to closely enclose the inside of the die, followed by filling the die with the resin. Taking the plurality of camera module bodies and the resin from the die is taking, from the die, the plurality of camera module bodies and the resin formed around the plurality of camera module bodies in close contact.

A camera module fabricated by the camera module fabricating method includes: a camera module body providing with a sensor board and a lens holder; and a shield blocking a light formed at the side surface of the camera module body in close contact.

The sensor board is a sensor board having a sensor unit. The lens holder is a lens holder secured on the sensor board and having a lens therein.

A detailed description will be given below of a camera module fabricating method and a camera module fabricated by the camera module fabricating method with reference to the attached drawings.

### First Embodiment

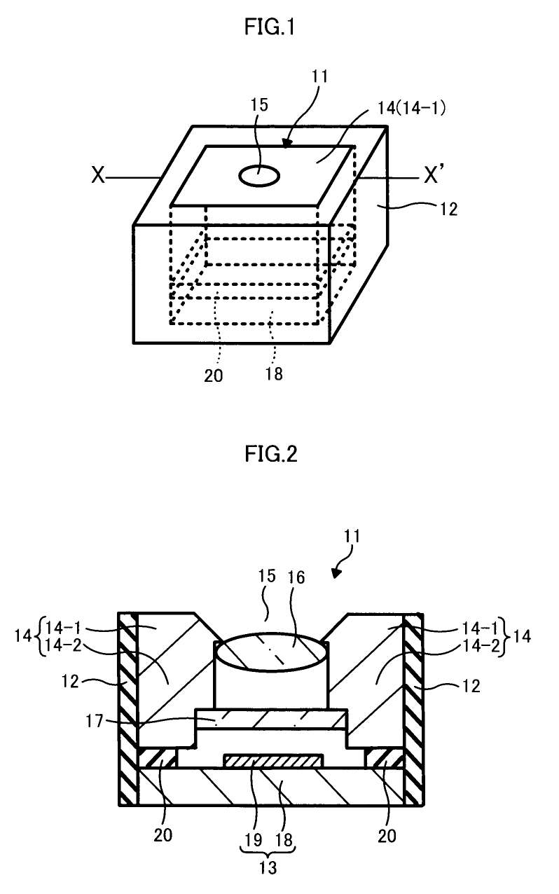

FIG. 1 is a perspective view showing a camera module fabricated by a camera module fabricating method in a first embodiment. As shown in FIG. 1, a camera module is constituted of a camera module body 11 and a shield 12 formed in such a manner as to surround the camera module body 11. The shield 12 shuts out a light.

Referring to FIG. 2, the structure of the camera module will be explained below in more detail. FIG. 2 is a cross-sectional view showing the camera module, taken along a line X-X′ of FIG. 1.

As shown in FIG. 2, the camera module body 11 comprises a sensor board 13 and a lens holder 14 secured on the sensor board 13.

The lens holder 14 constitutes of a cylindrical portion 14-1 and a top plate 14-2 disposed at the upper end of the cylindrical portion 14-1. The top plate 14-2 is formed into a substantially square shape, and further, has a hole 15 bored at the center thereof in a desired size.

The cylindrical portion 14-1 is formed into a substantially square shape in cross section of a plane parallel to the top plate 14-1, and further, incorporates a lens 16 and an infrared-ray cut filter 17 therein.

The lens 16 is disposed right under the hole 15 bored in the top plate 14-2 inside of the cylindrical portion 14-1. The infrared-ray cut filter 17 is disposed under the lens 16 and at a position separate from the lens 16 inside of the cylindrical portion 14-1.

The sensor board 13 constitutes of an insulating board 18 and a sensor unit 19 mounted on the insulating board 18. The sensor unit 19 is constituted of, for example, a plurality of imaging elements.

The lens holder 14 is located above the sensor board 13. The lens holder 14 is disposed on the sensor board 13 in such a manner that the cylindrical portion 14-1 covers the sensor unit 19. The lens holder 14 is secured above the sensor board 13 via an adhesive agent 20.

Here, the lens holder 14 is secured in the state in which its focus is adjusted. The focus is adjusted by adjusting the thickness of the adhesive agent 20. The adhesive agent 20 is an adhesive agent which is generally used such as a thermocurable adhesive agent or a photocurable adhesive agent.

The shield 12 is formed at the side surface of the camera module body 11 in close contact therewith. The shield 12 is made of a resin blocking a light.

In the above-described camera module, light incident inside through the hole 15 formed in the top plate 14-2 of the lens holder 14 is focused on the sensor unit 19 by the lens 16 contained inside of the lens holder 14. At this time, the incident light passes through the infrared-ray cut filter 17, and therefore, an infrared ray is excluded from the light reaching the sensor unit 19.

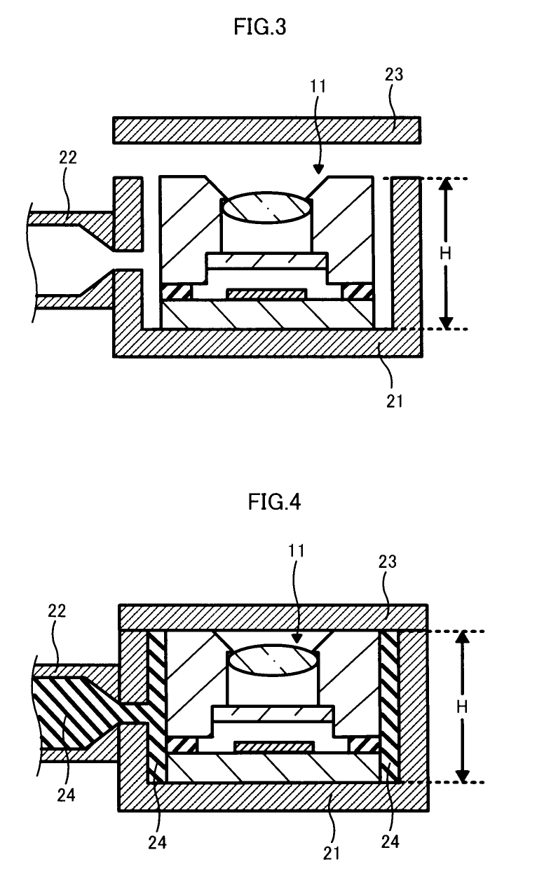

Next, a description will be given in detail of a method for fabricating the camera module shown in FIGS. 1 and 2 with reference to FIGS. 3 to 5. FIGS. 3 to 5 each are cross-sectional views illustrating the camera module fabricating method in the present embodiment and corresponding to FIG. 2. The description of the fabricating method will be given of states after the lens holder 14 is secured above the sensor board 13 by using an automatic assembling device. Specifically, explanation will be made on a method for forming the shield 12 in the camera module body 11.

First, as illustrated in FIG. 3, the camera module body 11 is disposed inside of a die 21 blocking a light. The die 21 is formed into a larger size than that of the camera module body 11. Specifically, the die 21 is formed into a bottomed cylindrical shape in conformity with the shape of the lens holder 14, and further, in a size enough that the side surface of the die 21 cannot be brought into contact with the camera module body 11. Moreover, the die 21 has substantially the same height H as that of the camera module body 11. Here, a sealing unit 22 for sealing a resin into the die 21 is attached at one side surface of the die 21.

The camera module body 11 may be automatically housed inside of the die 21 by using the automatic assembling device or may be manually housed, if possible. The means is not limited.

Subsequently, as illustrated in FIG. 4, the upper end of the die 21 which disposes therein the camera module body 11 is covered with a lid 23, so that the inside of the die 21 is tightly sealed. The die 21 has the inside height H which is substantially the same as that of the camera module body 11. Consequently, the upper portion of the camera module body 11 (i.e., the surface of the top plate 14-2 of the lens holder 14) and the lid 23 are brought into close contact with each other. In this state, the die 21 is filled with a thermocurable resin 24 such as an epoxy resin through the sealing unit 22. The resin 24 is a resin that shuts out a light. Here, the die 21 is filled with the resin 24, so that air staying inside of the die 21 until then is discharged to the outside of the die 21 through a discharge port, not illustrated, formed at a part of the die 21.

Next, as illustrated in FIG. 5, the die 21 is heated, so that the resin 24 filled inside of the die 21 is heated to be cured. Thereafter, the camera module body 11 covered with the shield 12 made of the resin 24 is taken from the inside of the die 21, thus obtaining the camera module in the present embodiment.

The camera module body 11 covered with the shield 12 may be automatically taken from the inside of the die 21 by using the automatic assembling device or may be manually taken, if possible. The means is not limited.

The camera module fabricated in the above-described processes is formed such that the camera module body 11 is covered with the shield 12 in close contact. Therefore, no clearance is defined between the camera module body 11 and the shield 12, unlike the camera module in the prior art. Thus, the camera module can be miniaturized.

In addition, even if the thickness of the lens holder 14 is reduced in order to further miniaturize the camera module body 11, the lens holder 14 is covered with the shield 12 in close contact, and therefore, the camera module can be miniaturized by setting the shield 12 in a desired thickness without degrading the mechanical strength and light blocking effect of the shield 12.

Additionally, the shield 12 is formed around the camera module body 11 in close contact, so that no light is incident through a clearance between the camera module body 11 and the shield 12. Thus, the camera module excellent in light blocking effect can be obtained.

### Second Embodiment

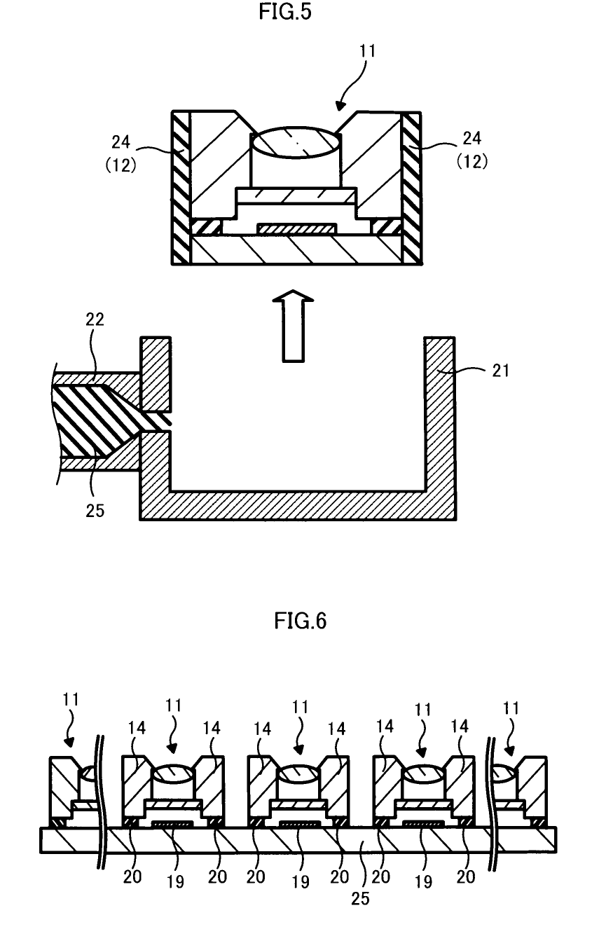

Next, a description will be given in detail of a method for fabricating a camera module in a second embodiment with reference to FIGS. 6 to 10. FIGS. 6 to 10 each are views illustrating the camera module fabricating method in the present embodiment and corresponding to FIG. 2. A camera module fabricated by the fabricating method is the same as that shown in FIGS. 1 and 2. Therefore, the description of the structure of the camera module will omitted below.

First, as illustrated in FIG. 6, a plurality of lens holders 14 are secured, via adhesive agents 20, on a wafer 25 having a plurality of sensor units 19 formed thereon in, for example, a grid manner. The lens holders 14 are secured by means such as an automatic assembling device, not shown.

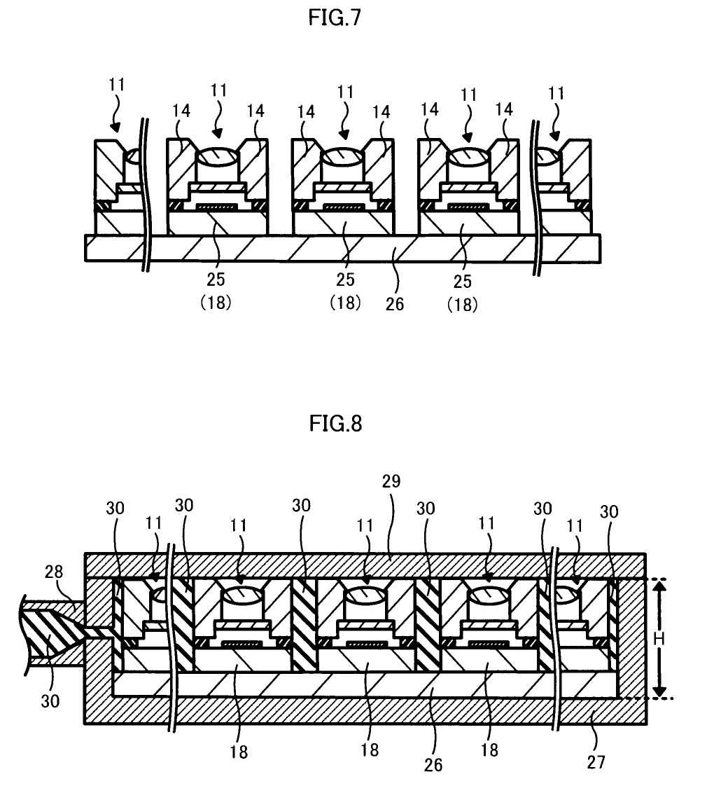

Subsequently, as illustrated in FIG. 7, a support board 26 is secured over the entire reverse of the wafer 25. The wafer 25 exposed to a clearance defined between the lens holders 14 arranged in the grid manner is etched until through the wafer 25. As a consequence, the wafer 25 exposed between the lens holders 14 is removed. In this manner, each of the lens holders 14 comes to be secured onto each of the wafers 25 (corresponding to the insulating board 18 in the first embodiment) split by etching, thereby fabricating a camera module body 11.

Subsequently, in the same manner as the first embodiment, that is, as illustrated in FIG. 8, the support board 26 and the plurality of camera module bodies 11 formed thereon are disposed inside of a die 27 blocking a light whose upper end is covered with a lid 29. Thereafter, the die 27 is filled with a thermocurable resin 30 such as an epoxy resin through a sealing unit 28 attached to one side surface of the die 27. The resin 30 is a resin that shuts out a light.

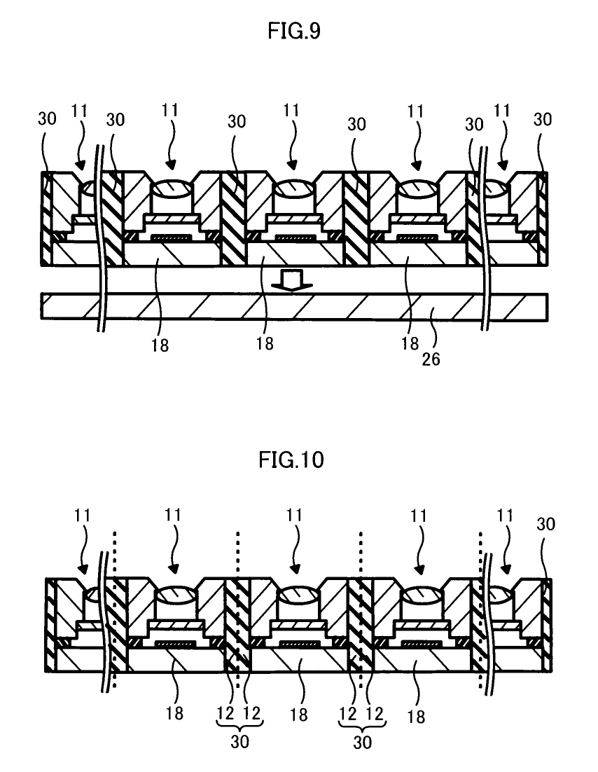

Next, as illustrated in FIG. 9, the filled resin 30 is heated, to be cured. And then, the plurality of camera module bodies 11 which are integrated with each other via the resin 30 are taken out of the die 27, and then, the support board 26 is detached from the plurality of camera module bodies 11.

Finally, as illustrated in FIG. 10, the resin 30 integrating the plurality of camera module bodies 11 is cut by dicing. In this manner, the plurality of camera module bodies 11 are individually cut in the state covered with the shield 12 made of the resin 30.

With the above-described processes, the camera module shown in FIGS. 1 and 2 can be fabricated.

The camera module fabricated by this method has the same shape as that shown in FIGS. 1 and 2. As a consequence, it is possible to miniaturize the camera module without degrading the mechanical strength and light blocking effect of the shield 12.

With this fabricating method, the plurality of camera modules can be fabricated at one time. Hence, the same number of camera modules as that fabricated by the camera module fabricating method in the first embodiment can be fabricated in a short period of time.

While certain embodiments have been described, these embodiments have been presented by way of example only, and are not intended to limit the scope of the inventions. Indeed, the novel fabricating methods and camera modules described herein may be embodied in a variety of other forms: furthermore, various omissions, substitutions and changes in the form of the fabricating methods and camera modules described herein may be made without departing from the spirit of the inventions. The accompanying claims and their equivalents are intended to cover such forms or modifications as would fall within the scope and spirit of the inventions.

For example, the resins 24 and 30 poured into the die 21, 27 in each of the embodiments may be, for example, resins mixed with a conductive filler made of metal powder of carbon black, metal powder of copper, or the like. The use of the resin mixed with the conductive filler can form a shield blocking a light and a magnetism.

Such a shield may be made of a conductive foil in place of a conductive filler. For example, a conductive foil is attached to a side surface of the camera module body 11 by vapor deposition.

Alternatively, the conductive foil may be attached to the side surface of the camera module body 11 by spraying metal. Or, the conductive foil may be attached to the side surface of the shield 12 by such means.

On the other hand, a photocurable resin such as an epoxy resin may be used as the resins 24 and 30 which are poured into the dies 21 and 27, respectively, in the embodiments. In this case, the dies 21 and 27 need be made of a material which transmits light having a wavelength at which at least the photocurable resin can be cured. The photocurable resin can be cured in a shorter time than the thermocurable resin. Therefore, the use of the photocurable resin enables the camera module to be fabricated in a shorter period of time.

The above-described method for fabricating the camera module in the embodiments according to the present invention is applicable to a method for fabricating a camera module having a camera module body of a structure different from that of the camera module shown in FIGS. 1 and 2.

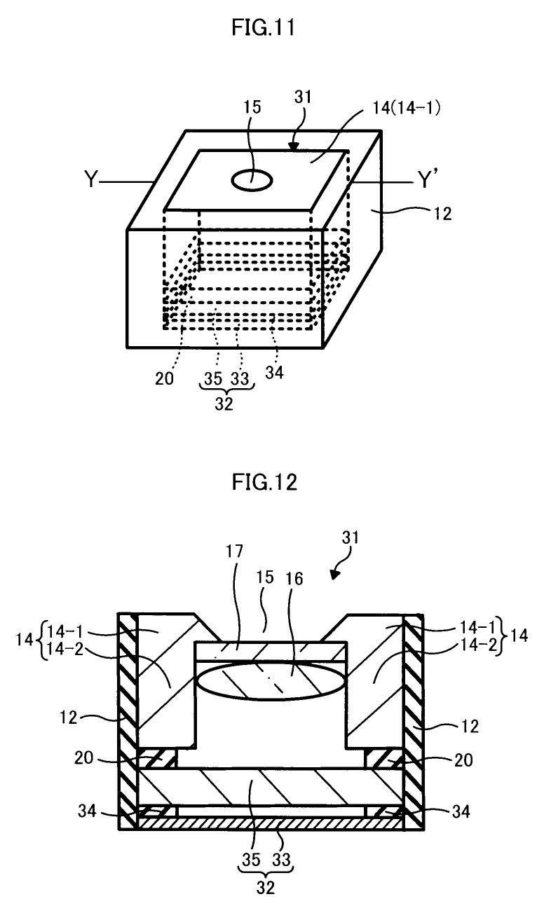

FIG. 11 is a perspective view showing a first modification of the camera module fabricated by the camera module fabricating method in each of the above-described embodiments. FIG. 12 is a cross-sectional view showing the camera module, taken along a line Y-Y′ of FIG. 11. As shown in FIG. 11, the camera module in the first modification is different in the structure of a camera module body 31, in particular, a sensor board 32. Specifically, the sensor board 32 in the camera module is constituted of a plate-like sensor unit 33, and a glass board 35 secured onto the sensor unit 33 via an adhesive agent 34. A lens holder 14 is fixed onto the sensor board 32, that is, the glass board 35 via an adhesive agent 20.

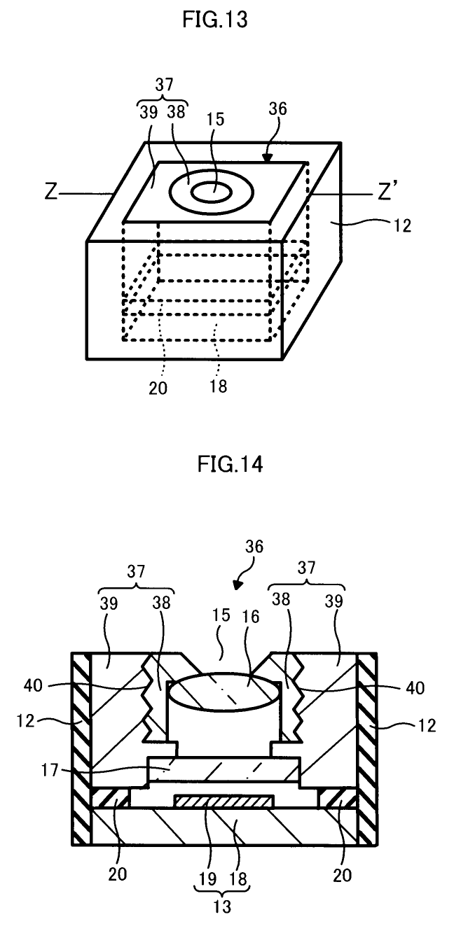

FIG. 13 is a perspective view showing a second modification of the camera module fabricated by the camera module fabricating method in each of the above-described embodiments. FIG. 14 is a cross-sectional view taken along a line Z-Z′ of FIG. 13. As shown in FIG. 13, the camera module in the second modification is different in the structure of a camera module body 36, in particular, a lens holder 37. Specifically, the lens holder 37 in the camera module is constituted of a first lens holder 38 having a lens 16 therein and providing with a hole 15 formed at the upper portion thereof and a second lens holder 39 including an infrared-ray cut filter 17 therein.

Screw grooves 40 are formed at the outside surface of the first lens holder 38 and the inside surface of the second lens holder 39. The first lens holder 38 is secured inside of the second lens holder 39 via the screw grooves 40.

The camera module fabricating method in the above-described embodiments may be applied to a method for fabricating the camera module illustrated in FIGS. 11 and 12 and the camera module illustrated in FIGS. 13 and 14. Here, the camera module to be utilized need not always be a camera module having the infrared-ray cut filter.

What is claimed is:

1. A method for fabricating a camera module comprising the steps of:
disposing a camera module body having a lens holder secured above a sensor board inside of a die in such a manner that the side surface of the camera module body is not brought into contact with the side surface of the die;
covering the upper end of the die with a lid so as to closely enclose the inside of the die, followed by filling the die with a resin blocking a light;
curing the resin; and
taking, from the die, the camera module body and the resin formed around the camera module body in close contact.

2. A method for fabricating a camera module according to claim 1, wherein the resin is a thermocurable resin; and
curing the resin comprises curing by heating the resin.

3. A method for fabricating a camera module according to claim 1, wherein the resin is a photocurable resin;
curing the resin comprises curing by irradiating the resin with light.

4. A method for fabricating a camera module comprising the steps of:
securing a plurality of lens holders on a surface of a wafer;
securing a support board at the reverse of the wafer;
removing the wafer exposed to a clearance between the lens holders so as to form a plurality of camera module bodies on the support board;
disposing the support board having the plurality of camera module bodies inside of a die in such a manner that the side surface of the camera module body is not brought into contact with the side surface of the die;
covering the upper end of the die with a lid so as to closely enclose the inside of the die, followed by filling the die with a resin blocking a light;
curing the resin;
taking, from the die, the plurality of camera module bodies and the resin formed around the plurality of camera module bodies in close contact;
taking out the support board from the plurality of camera module bodies; and
dicing the resin staying between the camera module bodies.

5. A method for fabricating a camera module according to claim 4, wherein the resin is a thermocurable resin; and
curing the resin comprises curing by heating the resin.

6. A method for fabricating a camera module according to claim 4, wherein the resin is a photocurable resin;
curing the resin comprises curing by irradiating the resin with light.

7. A camera module comprising:
a camera module body including:
a sensor board having a sensor unit; and
a lens holder secured on the sensor board and containing a lens therein; and
a shield made of a resin blocking a light and formed at the side surface of the camera module body in close contact.

8. A camera module according to claim 7, wherein the resin is a resin blocking a light and having a conductive filler mixed therein.

9. A camera module according to claim 8, wherein the conductive filler is either metal powder of carbon black or metal powder of copper.

10. A camera module according to claim 7, wherein the sensor board comprises:
an insulating board; and
a sensor unit disposed on the insulating board.

11. A camera module according to claim 7, wherein the sensor board comprises:
a sensor unit; and
a glass board secured on the sensor unit via an adhesive agent.

12. A camera module according to claim 7, wherein the lens holder comprises:
a first lens holder incorporating a lens therein; and
a second lens holder provided at the outside surface of the first lens holder.
